(19) United States
(12) Patent Application Publication
(10) Pub. No.: US 2023/0176485 A1
(43) Pub. Date: Jun. 8, 2023

(54) APPARATUS FOR TREATING SUBSTRATE AND METHOD FOR TREATING SUBSTRATE

(71) Applicant: SEMES CO., LTD., Cheonan-si (KR)

(72) Inventors: DONGWOON PARK, Seoul (KR); GI HUN JUNG, Cheonan-si (KR); JIN TAEK OH, Asan-si (KR); TAE SHIN KIM, Suwon-si (KR); JU WON KIM, Yongin-si (KR); A RAH CHO, Daejeon (KR); BYOUNG DOO CHOI, Cheonan-si (KR)

(73) Assignee: SEMES CO., LTD., Cheonan-si (KR)

(21) Appl. No.: 18/073,568

(22) Filed: Dec. 2, 2022

(30) Foreign Application Priority Data
Dec. 2, 2021 (KR) 10-2021-0171041

(51) Int. Cl. G03F 7/38

(52) U.S. Cl. CPC G03F 7/38

(57) ABSTRACT

Provided is a method for treating a substrate. The method for treating the substrate may include heating a substrate formed with a plurality of thin film layers including a photoresist layer formed on a surface, and irradiating light to a first thin film layer including a metal among the plurality of thin film layers to heat the first thin film layer.

### CROSS-REFERENCE TO RELATED APPLICATIONS

This application claims priority to and the benefit of the Korean Patent Application No. 10-2021-0171041 filed in the Korean Intellectual Property Office on Dec. 2, 2021, the entire contents of which are herein incorporated by reference.

### TECHNICAL FIELD

The present invention relates to an apparatus for treating a substrate and a method for treating a substrate, and more particularly, to a substrate treating apparatus and a substrate treating method for heating a substrate.

### BACKGROUND ART

In order to manufacture semiconductor devices, various processes such as cleaning, deposition, photolithography, etching, and ion-implantation are performed. Among these processes, the photolithography process includes a coating process of coating a photosensitive liquid such as a photoresist on the surface of a substrate to form a film, an exposure process of transferring a circuit pattern to the film formed on the substrate, and a developing process of removing the film formed on the substrate selectively from an exposed region or an opposite region thereto.

In the developing process, a process of heat-treating a thin film layer formed on the substrate is performed. A general heat-treating process indirectly transfers heat to the thin film layer formed on the substrate using a heating plate provided below the substrate. In the same manner, since the heat is indirectly transferred to the substrate, it is difficult to control the uniformity to transfer the heat to the thin film layer formed on the substrate.

In addition, the thin film layer formed on the substrate is directly heated by irradiating a heat source vertically from the top of the substrate. In the same manner, since the heat source is vertically irradiated on the substrate, the pattern formed below the substrate may be damaged. In addition, when the intensity of the heat source is not precisely controlled, it is difficult to selectively heat a specific thin film layer among a plurality of thin film layers.

### SUMMARY OF THE INVENTION

An object of the present invention is to provide a substrate treating apparatus and a substrate treating method capable of efficiently treating the substrate.

Another object of the present invention is to provide a substrate treating apparatus and a substrate treating method capable of selectively heating a thin film layer formed on the substrate.

Yet another object of the present invention is to provide a substrate treating apparatus and a substrate treating method capable of minimizing damage to a pattern formed on a thin film layer when heating the thin film layer formed on the substrate.

Still another object of the present invention is to provide a substrate treating apparatus and a substrate treating method capable of using a specific layer as a heat source by heating the specific layer of a thin film layer formed on the substrate.

Other objects of the present invention are not limited thereto, and other objects, which are not mentioned above, will be apparent to those skilled in the art from the following description.

An embodiment of the present invention provides a method for treating a substrate. The method for treating the substrate may include heating a substrate formed with a plurality of thin film layers including a photoresist layer formed on a surface, and irradiating light to a first thin film layer including a metal among the plurality of thin film layers to heat the first thin film layer.

In an embodiment, the light may be laser light.

In an embodiment, the laser light may be incident obliquely on an upper surface of the first thin film layer.

In an embodiment, the first thin film layer may be a layer formed under the photoresist layer.

In an embodiment, the first thin film layer may be the photoresist layer.

In an embodiment, an area where the laser light is irradiated to the first thin film layer may be changed while the laser light is irradiated to the first thin film layer.

In an embodiment, the change of the irradiation area of the laser light may be performed by moving the substrate while the laser light is irradiated.

In an embodiment, while the area to which the laser light is irradiated is changed, an incident angle of the laser light may be maintained in the same manner.

In an embodiment, the heat treating may be performed after exposure treatment on the substrate.

Another embodiment of the present invention provides a heating method for a substrate in a photolithography process including a coating process of coating a photoresist on the substrate, an exposure process of irradiating light to the substrate, and a developing process of supplying a developer to the substrate. The heating method may include heating a substrate formed with a plurality of thin film layers including a photoresist layer formed on a surface, and irradiating light to a first thin film layer including a metal among the plurality of thin film layers to heat the first thin film layer.

In the embodiment, the laser light may be incident obliquely on an upper surface of the first thin film layer.

In an embodiment, the first thin film layer may be a layer formed under the photoresist layer.

In an embodiment, the first thin film layer may be the photoresist layer.

In an embodiment, an area where the laser light is irradiated to the first thin film layer may be changed while the laser light is irradiated to the first thin film layer, and the change of the irradiation area of the laser light may be performed by moving the substrate while the laser light is irradiated.

In an embodiment, the heat treating may be performed after the exposure process.

Yet another embodiment of the present invention provides an apparatus for treating a substrate formed with a plurality of thin film layers including a photoresist layer formed on a surface. The apparatus for treating the substrate may include a housing having a treating space, a support unit positioned in the treating space to support the substrate, and a heating unit for heating the substrate, in which the heating unit may be provided to heat a first thin film layer by irradiating laser light to the first thin film layer including a metal among the plurality of thin film layers.

In an embodiment, the laser light may be incident obliquely on an upper surface of the first thin film layer.

In an embodiment, the first thin film layer may be a layer formed under the photoresist layer.

In an embodiment, the first thin film layer may be the photoresist layer.

In an embodiment, the apparatus for treating the substrate may further include a controller is configured to control the support unit, in which the support unit may include a support part for supporting the substrate, and a moving stage part for changing a position of the support part, in which the controller may control the moving stage part so that an area where the laser light is irradiated to the first thin film layer is changed, while the laser light is irradiated to the first thin film layer.

According to the embodiment of the present invention, it is possible to efficiently treat the substrate.

In addition, according to the embodiment of the present invention, it is possible to selectively heat the thin film layer formed on the substrate.

In addition, according to the embodiment of the present invention, it is possible to minimize the damage to a pattern formed on the thin film layer when heating the thin film layer formed on the substrate.

In addition, according to the embodiment of the present invention, it is possible to use a specific layer as a heat source by heating the specific layer of the thin film layer formed on the substrate.

The effect of the present invention is not limited to the foregoing effects, and non-mentioned effects will be clearly understood by those skilled in the art from the present specification and the accompanying drawings.

### BRIEF DESCRIPTION OF THE DRAWINGS

FIG. 1 is a perspective view schematically illustrating a substrate treating apparatus according to an embodiment of the present invention.

FIG. 2 is a front view of the substrate treating apparatus illustrating a coating block or a developing block of FIG. 1.

FIG. 3 is a plan view of the substrate treating apparatus of FIG. 1.

FIG. 4 is a view illustrating an embodiment of a hand provided in a transfer chamber of FIG. 3.

FIG. 5 is a view schematically illustrating an embodiment of a first heat treating chamber of FIG. 3.

FIG. 6 is a view schematically illustrating an embodiment of a second heat treating chamber of FIG. 3.

FIG. 7 is a view schematically illustrating an embodiment of a liquid treating chamber of FIG. 3.

FIG. 8 is a flowchart of a substrate treating method according to an embodiment of the present invention.

FIG. 9 is a view schematically illustrating a substrate on which an exposure process of FIG. 8 has been completed when viewed from the front.

FIG. 10 is a view schematically illustrating a state in which laser light is irradiated to a first thin film layer in a post bake process of FIG. 8.

FIG. 11 is an enlarged view of part A showing a state in which a heat source is transmitted from the first thin film layer of FIG. 10.

FIG. 12 is a view illustrating a start point of the post bake process of FIG. 8.

FIG. 13 is a view illustrating an end point of the post bake process of FIG. 8.

FIG. 14 is a view schematically illustrating a state in which laser light is irradiated to a photoresist layer in the post bake process of FIG. 8.

### DETAILED DESCRIPTION

Hereinafter, embodiments of the present invention will be described in more detail with reference to the accompanying drawings. Embodiments of the present invention may be modified in various forms and should not be construed that the scope of the present invention is limited to embodiments to be described below. The embodiments will be provided for more completely explaining the present invention to those skilled in the art. Therefore, shapes, and the like of components in the drawings are exaggerated to emphasize a more clear description.

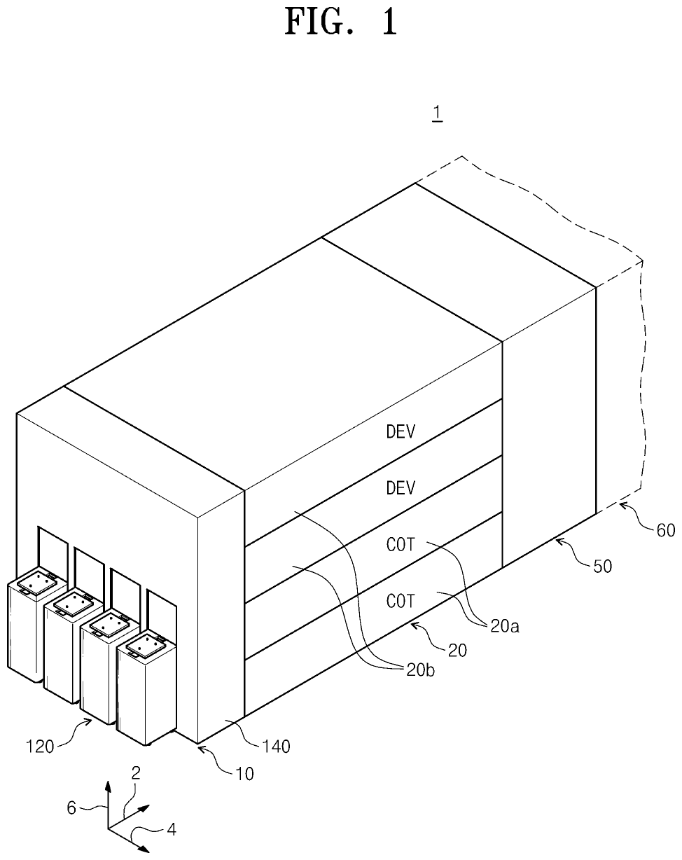

Hereinafter, an embodiment of the present invention will be described in detail with reference to FIGS. 1 to 14.

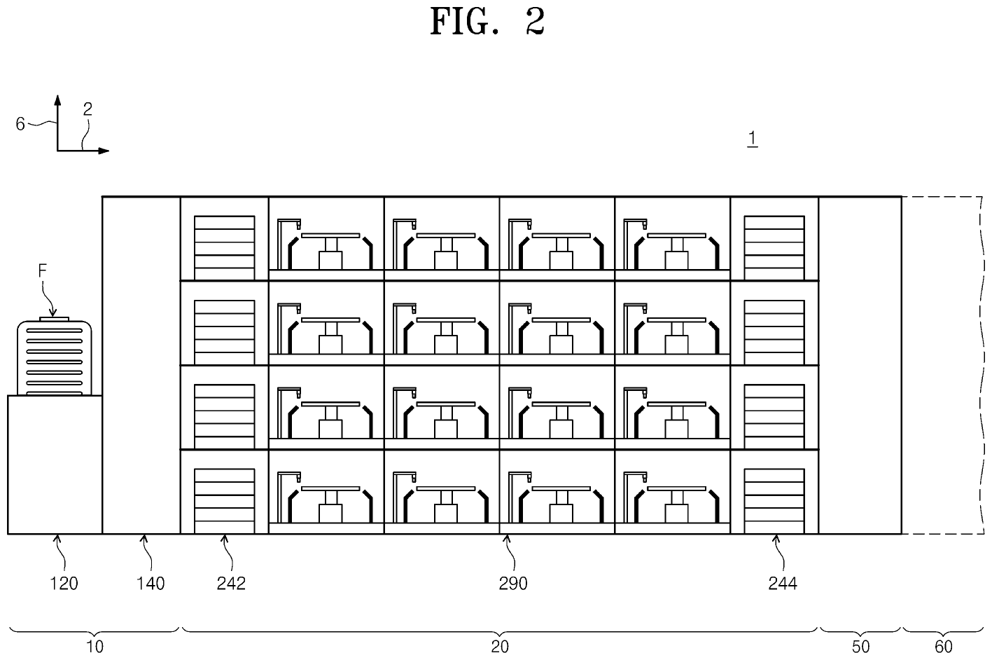

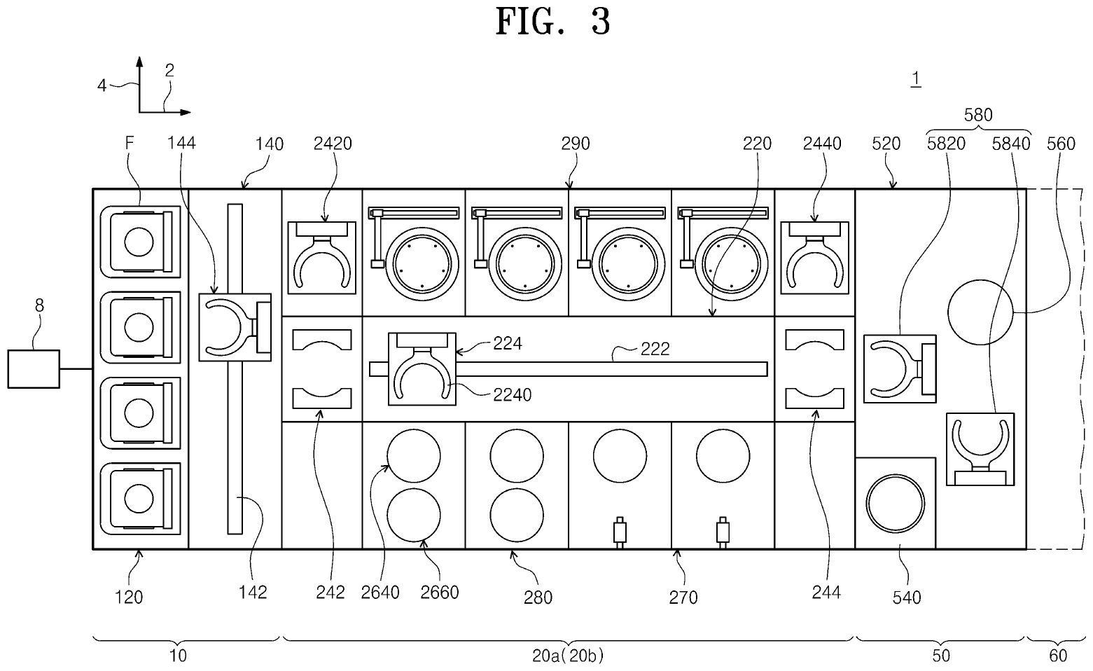

FIG. 1 is a perspective view schematically illustrating a substrate treating apparatus according to an embodiment of the present invention. FIG. 2 is a front view of the substrate treating apparatus illustrating a coating block or a developing block of FIG. 1. FIG. 3 is a plan view of the substrate treating apparatus of FIG. 1.

Referring to FIGS. 1 to 3, a substrate treating apparatus 1 includes an index module 10, a treating module 20, and an interface module 50. According to an embodiment, the index module 10, the treating module 20, and the interface module 50 are sequentially arranged in a line. Hereinafter, a direction in which the index module 10, the treating module 20, and the interface module 50 are arranged is defined as a first direction 2, a direction vertical to the first direction 2 when viewed from the top is defined as a second direction 4, and a direction vertical to both the first direction 2 and the second direction 4 is defined as a third direction 6.

The index module 10 transfers a substrate W to the treating module 20 for treating the substrate W from a container F in which the substrate W is accommodated. The index module 10 accommodates the substrate W that has been treated in the treating module 20 into the container F. The longitudinal direction of the index module 10 is provided as the second direction 4. The index module 10 has a load port 120 and an index frame 140.

The container F in which the substrate W is accommodated is seated on the load port 120. The load port 120 is located on an opposite side of the treating module 20 based on the index frame 140. A plurality of load ports 120 may be provided. The plurality of load ports 120 may be arranged in a line along the second direction 4. The number of load ports 120 may increase or decrease according to process efficiency and footprint conditions of the treating module 20.

A plurality of slots (not illustrated) is formed in the container F to accommodate the substrates W in a state of being disposed horizontally with the ground. As the container F, a sealed container such as a front opening unified pod (FOUP) may be used. The container F may be placed on the load port 120 by a transfer means (not illustrated) such as an overhead transfer, an overhead conveyor, or an automatic guided vehicle or by an operator.

An index rail 142 and an index robot 144 are provided inside the index frame 140. The index rail 142 is provided in the index frame 140 along the second direction 4 as its longitudinal direction. The index robot 144 may transfer the substrate W. The index robot 144 may transfer the substrate W between the load port 120 and a buffer chamber 240 to be described below. The index robot 144 may include an index hand 1440.

The substrate W may be placed on the index hand 1440. The index hand 1440 may include an index base 1442 and an index support 1444. The index base 1442 may have an annular ring shape of which a part of the circumference is cut away. The index support 1444 may move the index base 1442. The configuration of the index hand 1440 is the same as or similar to that of a transfer hand 2240 to be described below.

The index hand 1440 may be provided to be movable along the second direction 4 on the index rail 142. Accordingly, the index hand 1440 can move forward and backward along the index rail 142. In addition, the index hand 1440 may be provided to be rotatable in the third direction 6 as an axis and movable along the third direction 6.

The controller 8 may control the substrate treating apparatus 1. The controller 8 may include a process controller consisting of a microprocessor (computer) executing a control of the substrate treating apparatus 1, a keyboard for performing a command input operation and the like to manage the substrate treating apparatus 1 by an operator, a user interface consisting of a display and the like for visualizing and displaying an moving situation of the substrate treating apparatus 1, and a memory unit stored with control programs for executing treatment performed in the substrate treating apparatus 1 or programs, that is, treatment recipes for executing the treatment in each configuration unit according to various data and treatment conditions. In addition, the user interface and the memory unit may be connected to the process controller. The treatment recipes may be stored in a storage medium in the memory unit, and the storage medium may be a hard disk, and may also be a transportable disk such as a CD-ROM and a DVD, or a semiconductor memory such as a flash memory.

The controller 8 may control the substrate treating apparatus 1 to perform a substrate treating method to be described below. For example, the controller 8 may control components provided in a first heat treating chamber 270 to perform the substrate treating method to be described below.

The treating module 20 may receive the substrate W accommodated in the container F to perform a coating process and a developing process on the substrate W. The treating module 20 has a coating block 20a and a developing block 20b. The coating block 20a performs the coating process on the substrate W. The developing block 20b performs the developing process on the substrate W.

A plurality of coating blocks 20a is provided and the coating blocks 20a are provided to be stacked with each other. A plurality of developing blocks 20b is provided and the developing blocks 20b are provided to be stacked with each other. According to an embodiment, two coating blocks 20a may be provided, and two developing blocks 20b may be provided. The coating blocks 20a may be disposed under the developing blocks 20b. According to an embodiment, the two coating blocks 20a may perform the same process as each other, and may be provided in the same structure as each other. In addition, the two developing blocks 20b may perform the same process as each other, and may be provided in the same structure as each other. However, the present invention is not limited thereto, and the number and arrangement of the coating blocks 20a and the developing blocks 20b may be provided with various modifications.

Referring to FIG. 3, the coating block 20a may include a transfer chamber 220, a buffer chamber 240, a heat treating chamber 260, and a liquid treating chamber 290 for performing liquid treatment. The developing block 20b may include a transfer chamber 220, a buffer chamber 240, a heat treating chamber 260, and a liquid treating chamber 290 for performing liquid treatment.

The transfer chamber 220 provides a space in which the substrate W is transferred between the buffer chamber 240 and the heat treating chamber 260, between the buffer chamber 240 and the liquid treating chamber 290, and between the heat treating chamber 260 and the liquid treating chamber 290. The buffer chamber 240 provides a space in which the substrate W carried into the developing block 20b and the substrate W carried out from the developing block 20b temporarily stay. The heat treating chamber 260 performs a heat treating process on the substrate W. The heat treating process may include a heating process and/or a cooling process. The liquid treating chamber 290 performs a developing process of supplying a developer on the substrate W to develop the substrate W.

The transfer chamber 220, the buffer chamber 240, the heat treating chamber 260, and the liquid treating chamber 290 of the coating block 20a are provided in structure and arrangement substantially similar to the transfer chamber 220, the buffer chamber 240, the heat treating chamber 260, and the liquid treating chamber 290 of the developing block 20b. However, the liquid treating chamber 260 for performing the liquid treatment of the coating block 20a supplies the liquid on the substrate W to form a liquid film. The liquid film may be a photoresist film. Optionally, the liquid film may be a photoresist film or an anti-reflection film. According to an example, the liquid film supplied to the substrate W from the coating block 20a may be a photoresist film for extreme ultraviolet (EUV). Since the coating block 20a is provided in structure and arrangement substantially similar to those of the developing block 20b, a description thereof will be omitted. Hereinafter, the developing block 20b will be described.

The longitudinal direction of the transfer chamber 220 may be provided as the first direction 2. The transfer chamber 220 is provided with a guide rail 222 and a transfer robot 224. The longitudinal direction of the guide rail 222 is provided as the first direction 2. The transfer robot 224 may be provided to be movable in a straight line along the first direction 2 on the guide rail 222. The transfer robot 224 transfers the substrate W between the buffer chamber 240 and the heat treating chamber 260, between the buffer chamber 240 and the liquid treating chamber 290, and between the heat treating chamber 260 and the liquid treating chamber 290.

According to an example, the transfer robot 224 has a transfer hand 2240 on which the substrate W is placed. The transfer hand 2240 may be provided to be movable forward and backward, rotatable on an axis of the third direction 6, and movable along the third direction 6.

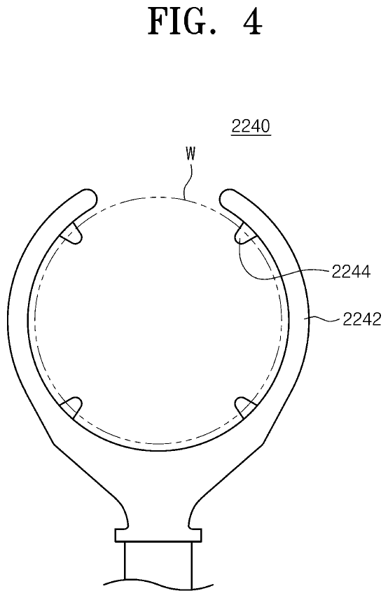

FIG. 4 is a view illustrating an embodiment of a hand provided in the transfer chamber of FIG. 3. Referring to FIG. 4, the transfer hand 2240 has a base 2242 and a support protrusion 2244. The base 2242 may have an annular ring shape of which a part of the circumference is cut away. The base 2242 may have an annular ring shape of which a part of the circumference is symmetrically cut away. The base 2242 has an inner diameter greater than the diameter of the substrate W. The support protrusion 2244 extends inward from the base 2242. A plurality of support protrusions 2244 is provided, and supports an edge region of the substrate W. According to an example, four support protrusions 2244 may be provided at equal intervals.

Referring back to FIGS. 2 and 3, a plurality of buffer chambers 240 is provided. Some of the buffer chambers 240 are disposed between the index module 10 and the transfer chamber 220. Hereinafter, these buffer chambers are referred to as front buffers 242. A plurality of front buffers 242 is provided and located to be stacked with each other in a vertical direction. Some of the buffer chambers 240 are disposed between the transfer chamber 220 and the interface module 50. Hereinafter, these buffer chambers are referred to as rear buffers 244. A plurality of rear buffers 244 is provided and located to be stacked with each other in a vertical direction.

The front buffers 242 and the rear buffers 244 temporarily store the plurality of substrates W, respectively. The substrates W stored in the front buffers 242 are carried into or out by the index robot 144 and the transfer robot 224. The substrates W stored in the rear buffers 244 are carried into or out by the transfer robot 224 and a first robot 5820 to be described below.

Buffer robots 2420 and 2440 may be provided on one side of the buffer chamber 240. The buffer robots 2420 and 2440 may include a front buffer robot 2420 and a rear buffer robot 2440. The front buffer robot 2420 may be provided on one side of the front buffer 242. The rear buffer robot 2440 may be provided on one side of the rear buffer 244. The present invention is not limited thereto, and the buffer robots 2420 and 2440 may be provided on both sides of the buffer chamber 240.

The front buffer robot 2420 may transfer the substrate W between the front buffers 242. The front buffer robot 2420 may include a front buffer hand 2422. The front buffer hand 2422 may be moved in a vertical direction along the third direction 6. The front buffer hand 2422 may be rotated. The rear buffer robot 2440 may transfer the substrate W between the rear buffers 244. The rear buffer robot 2440 may include a rear buffer hand 2442. The configuration of the rear buffer hand 2442 is the same as or similar to that of the front buffer hand 2422. Accordingly, a duplicated description of the rear buffer hand 2442 will be omitted.

A plurality of heat treating chambers 260 is provided. The heat treating chambers 260 are disposed along the first direction 2. The heat treating chambers 260 are disposed on one side of the transfer chamber 220. The heat treating chamber 260 may perform a heat treating process on the substrate W. The heat treating chamber 260 may perform cooling and/or heating on the substrate W.

The heat treating chamber 260 may include a first heat treating chamber 270 and a second heat treating chamber 280. As an example, the first heat treating chamber 270 may perform heat treatment for heating the substrate W. In the first heat treating chamber 270, a post exposure bake (PEB) process may be performed after the exposure process on the substrate W has been completed in an exposure device 60. As an example, the second heat treating chamber 280 may perform cooling and heating the substrate W. In the second heat treating chamber 280, a hard bake process of heating and/or cooling the substrate W may be performed after performing the developing process by supplying a developer on the substrate W in the liquid treating chamber 290 to be described below. However, the present invention is not limited thereto, and the first heat treating chamber 270 may also perform both the post bake and the hard bake. In addition, the second heat treating chamber 280 may also perform both the post bake and the hard bake.

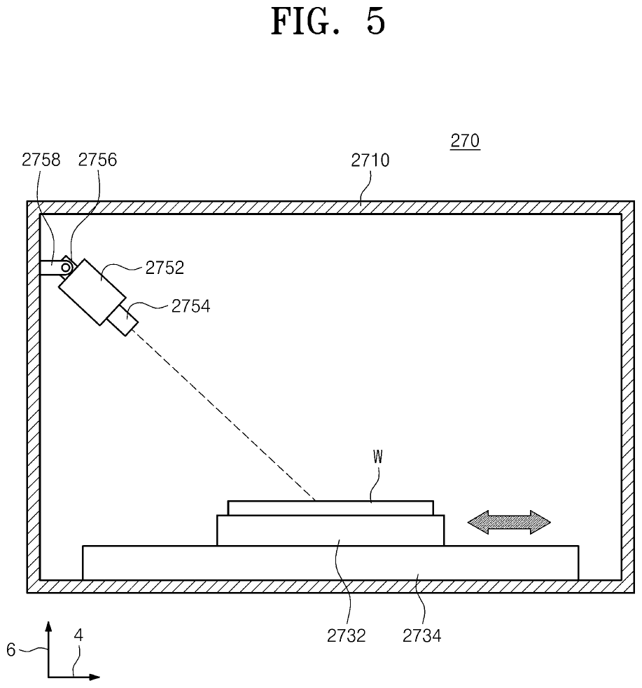

FIG. 5 is a view schematically illustrating an embodiment of the first heat treating chamber of FIG. 3. Referring to FIG. 5, the first heat treating chamber 270 may include a housing 2710, a support unit 2730, and a heating unit 2750.

The housing 2710 has a treating space therein. The treating space of the housing 2710 may be a space in which heat treatment on the substrate W is performed. On a side wall of the housing 2710, an entrance (not illustrated) through which the substrate W is carried in or out is formed. The support unit 2730 and the heating unit 2750 may be positioned inside the housing 2710.

The support unit 2730 supports the substrate W. The support plate 2730 may be a chuck that supports the substrate W. The support unit 2730 may include a support part 2732 and a moving stage part 2734. The support part 2732 may have an upper surface for supporting the substrate W. An adsorption hole (not illustrated) is formed in the support part 2732 to chuck the substrate W by a vacuum adsorption method. Optionally, the support part 2732 may be provided with an electrostatic pin (not illustrated) to chuck the substrate W by an electrostatic adsorption method using static electricity. Optionally, support pins (not illustrated) for supporting the lower surface of the substrate W may be provided on the upper surface of the support part 2732. The support pins (not illustrated) and the substrate W may be physically in contact with each other.

The moving stage part 2734 may be coupled to a lower end of the support part 2732. The moving stage part 2734 may move the support part 2732. When the moving stage part 2734 moves the support part 2732, the substrate W supported by the support part 2732 may also be moved. For example, the moving stage part 2734 may move the support part 2732 in the first direction 2. In addition, the moving stage part 2734 may move the support part 2732 in the second direction 4. The moving stage part 2734 may receive power from a driver (not illustrated) to move the support part 2732 in the first direction 2 and the second direction 4. An actuator (not illustrated) may be provided as any one of known devices for generating power, such as a motor for generating a driving force, a pneumatic cylinder, a hydraulic cylinder, or a solenoid.

The heating unit 2750 may heat-treat the substrate W. For example, the heating unit 2750 may heat the substrate W supported by the support unit 2730. The heating unit 2750 may target and heat a specific layer formed on the substrate W. The heating unit 2750 may heat a specific layer among a plurality of thin film layers DL in the substrate W having the plurality of thin film layers DL including a photoresist layer PR formed on the surface thereof. For example, the heating unit 2750 may be a laser module for irradiating laser light L. The heating unit 2750 according to an embodiment of the present invention may irradiate laser light to a first thin film layer TL including a metal among the plurality of thin film layers DL including the photoresist layer PR.

The heating unit 2750 may include a laser irradiator 2752, a beam expander 2754, a tilting member 2756, and a fixing member 2758. The laser irradiator 2752 irradiates the laser light L. The laser irradiator 2752 may irradiate laser light L having straightness. The laser irradiator 2752 may be disposed to be inclined with respect to the ground by the tilting member 2756 to be described below. The laser irradiator 2752 may be disposed to be inclined from the upper surface of the substrate W supported by the support unit 2730. For example, as illustrated in FIG. 5, the laser light L having straightness irradiated from the laser irradiator 2752 may be obliquely incident on the upper surface of the substrate W. Also, the laser light L irradiated from the laser irradiator 2752 may be obliquely incident on the upper surface of the first thin film layer TL including the metal formed on the substrate W.

The beam expander 2754 may control the characteristics of the laser light L irradiated from the laser irradiator 2752. The beam expander 2754 may control the shape of the laser light L irradiated from the laser irradiator 2752. In addition, the beam expander 2754 may control the profile of the laser light L irradiated from the laser irradiator 2752. For example, the diameter, wavelength, frequency, or the like of the laser light L irradiated from the laser irradiator 2752 may be changed in the beam expander 2754.

The tilting member 2756 may be coupled to the laser irradiator 2752. The tilting member 2756 may control an angle of the laser irradiator 2752. Accordingly, the tilting member 2756 may position the laser irradiator 2752 to be inclined on the ground. The laser light L irradiated from the laser irradiator 2752 may be obliquely incident on the upper surface of the substrate W by the tilting member 2757. The fixing member 2758 may be coupled to the side wall of the housing 2710. One end of the fixing member 2758 may be coupled to one side wall of the housing 2710, and the other end of the fixing member 2758 may be coupled to the tilting member 2756. Unlike described above, the laser irradiator 2752 of the heating unit 2750 may also be horizontally moved, vertically moved, or rotated by a shaft and an actuator coupled to the shaft.

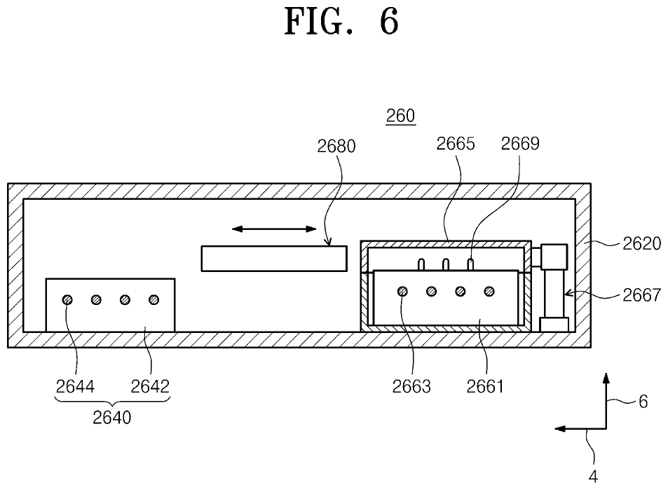

FIG. 6 is a view schematically illustrating an embodiment of the second heat treating chamber of FIG. 3. Referring to FIG. 6, the second heat treating chamber 280 may include a housing 2620, a cooling unit 2640, a heating unit 2660, and a transfer plate 2680.

The housing 2620 is provided in a substantial cuboid shape. The housing 2620 provides a space therein. On a side wall of the housing 2620, an entrance (not illustrated) through which the substrate W is carried into or out is formed. The entrance may be kept in an open state. Optionally, a door (not illustrated) may be provided to open and close the entrance. The cooling unit 2640, the heating unit 2660, and the transfer plate 2680 are provided in an inner space of the housing 2620.

The cooling unit 2640 and the heating unit 2660 are provided in parallel along the second direction 4. According to an example, the cooling unit 2640 may be positioned relatively closer to the transfer chamber 220 than the heating unit 2660. The cooling unit 2640 includes a cooling plate 2642. The cooling plate 2642 may have a substantially circular shape when viewed from the top. A cooling member 2644 is provided in the cooling plate 2642. According to an example, the cooling member 2644 is formed inside the cooling plate 2642, and may be provided as a flow channel in which a cooling fluid flows.

The heating unit 2660 includes a heating plate 2661, a heater 2663, a cover 2665, and an actuator 2667. The heating plate 2661 has a substantially circular shape when viewed from the top. The heating plate 2661 has a diameter greater than the substrate W. The heating plate 2661 is provided with a heater 2663. The heater 2663 may be provided as a heating resistor to which a current is applied. The heating plate 2661 is provided with lift pins 2669 that can be driven in a vertical direction along the third direction 6. The lift pins 2669 receive the substrate W from a transfer means outside the heating unit 2669 and puts down the substrate W on the heating plate 2661 or lifts the substrate W from the heating plate 2661 to transfer the substrate W to the transfer means outside the heating unit 2660. The cover 2665 has a space with an opened lower portion therein. The cover 2665 is positioned above the heating plate 2661 and is moved in the vertical direction by the actuator 2667. The cover 2665 is moved so that a space formed with the cover 2665 and the heating plate 2661 is provided as a heating space for heating the substrate W.

The transfer plate 2680 is provided in a substantial disk shape and has a diameter corresponding to the substrate W. The transfer plate 2680 may receive or transfer the transfer hand 2240 and the substrate W. The transfer plate 2680 is mounted on the guide rail 2692 and may move the upper portion of the cooling unit 2640 and the upper portion of the heating unit 2660 along the guide rail 2692 by the actuator 2694. The transfer plate 2680 is provided with a material having high thermal conductivity so that the heat transfer between the cooling plate 2642 and the substrate W is made well. According to an example, the transport plate 2680 may be made of a metal material.

Referring back to FIGS. 2 and 3, a plurality of liquid treating chambers 290 for performing liquid treatment is provided. Some of the liquid treating chambers 290 may be provided to be stacked with each other. The liquid treating chambers 290 are disposed on one side of the transfer chamber 220. The liquid treating chambers 290 are arranged in parallel along the first direction 2.

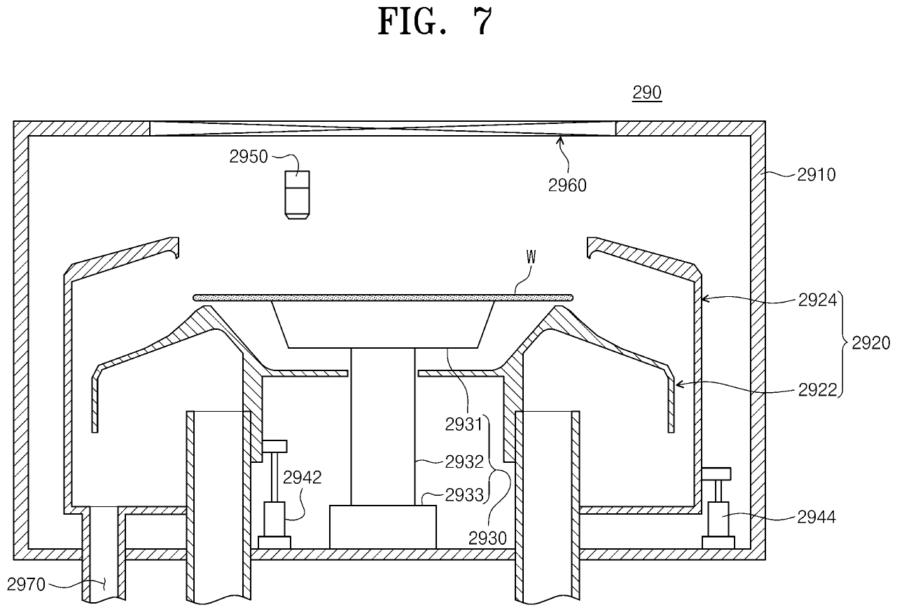

FIG. 7 is a view schematically illustrating an embodiment of the liquid treating chamber of FIG. 3. Referring to FIG. 7, the liquid treating chamber 290 may include a housing 2910, a treating container 2920, a support unit 2930, an elevation unit 2940, and a liquid supply unit 2950.

The housing 2910 provides a space therein. The housing 2910 is provided in a substantially cuboid shape. An opening (not illustrated) is formed in one side of the housing 2910. The opening functions as an entrance through which the substrate W is carried into the inner space or the substrate W is carried out from the inner space. In addition, in order to selectively seal the entrance, a door (not illustrated) may be provided in an area adjacent to the entrance. The door may seal the inner space by blocking the entrance while the treating process on the substrate W carried into the inner space is performed. The treating container 2920, the support unit 2930, the elevation unit 2940, and the liquid supply unit 2950 are disposed in the housing 2910.

The treating container 2920 may have a treating space with an opened upper portion. The treating container 2920 may be a bowl having a treating space. The inner space may be provided to cover the treating space. The treating container 2920 may have a cup shape with an opened upper portion. The treating space of the treating container 2920 may be a space in which the support unit 2930 to be described below supports and rotates the substrate W. The treating space may be a space in which the liquid supply unit 2950 to be described below supplies a fluid to treat the substrate W.

According to an example, the treating container 2920 may include an inner cup 2922 and an outer cup 2924. The outer cup 2924 is provided to surround the circumference of the support unit 2930, and the inner cup 2922 may be located inside the outer cup 2924. Each of the inner cup 2922 and the outer cup 2924 may have an annular ring shape when viewed from the top. A space between the inner cup 2922 and the outer cup 2924 may be provided as a recovery path through which the fluid introduced into the treating space is recovered.

The inner cup 2922 may be provided in a shape surrounding a support shaft 2932 of the support unit 2930 to be described below when viewed from the top. For example, the inner cup 2922 may be provided in a circular plate shape surrounding the support shaft 2932 when viewed from the top.

The outer cup 2924 may be provided to have a cup shape surrounding the support unit 2930 and the inner cup 2922. The outer cup 2924 may be formed with a bottom portion, a side portion, and an inclined portion. The bottom portion of the outer cup 2924 may have a hollow plate shape. A recovery line 2970 may be connected to the bottom portion of the outer cup 2924. The recovery line 2970 may recover a treating medium supplied onto the substrate W. The treating medium recovered by the recovery line 2970 may be reused by an external recycling system (not illustrated).

The side portion of the outer cup 2924 may have an annular ring shape surrounding the support unit 2930. The inclined portion of the outer cup 2924 may be provided to have a ring shape. The inclined portion of the outer cup 2924 may extend from an upper end of the side portion toward a central axis of the outer cup 2924. The inner surface of the inclined portion of the outer cup 2924 may be formed to be inclined upward to approach the support unit 2930. In addition, the upper end of the inclined portion of the outer cup 2924 may be positioned higher than the substrate W supported by the support unit 2930 while the substrate W is treated.

The support unit 2930 supports the substrate W in the treating space and rotates the substrate W. The support unit 2930 may be a chuck for supporting and rotating the substrate W. The support unit 2930 may include a body 2931, a support shaft 2932, and a driver 2933. The body 2931 may have an upper surface on which the substrate W is mounted. The upper surface of the body 2931 is provided in a substantially circular shape when viewed from the top. The upper surface of the body 2931 may be provided to have a diameter smaller than that of the substrate W.

The support shaft 2932 is coupled to the body 2931. The support shaft 2932 may be coupled to a lower surface of the body 2931. The support shaft 2932 may be provided so that a longitudinal direction thereof faces a vertical direction. The support shaft 2932 is provided to be rotatable by receiving power from the driver 2933. The support shaft 2932 rotates by rotation of the driver 2933 to rotate the body 2931. The driver 2933 may vary a rotation speed of the support shaft 2932. The driver 2933 may be a motor for providing a driving force. However, the present invention is not limited thereto and may be variously modified to known devices for providing the driving force.

The elevation unit 2940 controls a relative height between the treating container 2920 and the support unit 2930. The elevation unit 2940 linearly moves the treating container 2920 in the third direction 6. The elevation unit 2940 may include an inner elevation member 2942 and an outer elevation member 2944. The inner elevation member 2942 may elevate and move the inner cup 2922. The outer elevation member 2944 may elevate and move the outer cup 2924.

The liquid supply unit 2950 may supply a liquid onto the substrate W supported by the support unit 2830. The liquid supplied to the substrate W by the liquid supply unit 2950 may be a developer. In addition, the liquid supplied to the substrate W by the liquid supply unit 2950 may be deionized water (DIW). In addition, the liquid supply unit 2950 may also supply nitrogen (N2) to the substrate W. Although it is illustrated in FIG. 7 that the single liquid supply unit 2950 is provided, the present invention is not limited thereto, and a plurality of liquid supply units 2950 may be provided.

An airflow supply unit 2860 may be installed above the housing 2810. The airflow supply unit 2860 supplies an airflow to an inner space of the housing 2810. The airflow supply unit 2860 may supply a downflow to the inner space. The airflow supply unit 2860 may supply a temperature and/or humidity-controlled airflow to the inner space.

Referring back to FIGS. 1 to 3, the interface module 50 connects the treating module 20 and the external exposure device 60. The interface module 50 may include an interface frame 520, an additional liquid treating chamber 540, an interface buffer 560, and a transfer member 580.

The interface frame 520 provides an inner space. A fan filter unit may be provided at an upper end of the interface frame 520 to form a downflow in the inner space. The additional liquid treating chamber 540, the interface buffer 560, and the transfer member 580 are provided in the inner space of the interface frame 520.

The additional liquid treating chamber 540 may perform a predetermined additional process before the substrate W of which the process has been completed in the coating block 20a is carried into the exposure device 60. Optionally, the additional liquid treating chamber 540 may perform a predetermined additional process before the substrate W of which the process has been completed in the exposure device 60 is carried into the developing block 20b. According to an example, the additional process may be an edge exposure process of exposing an edge region of the substrate W, an upper surface cleaning process of cleaning an upper surface of the substrate W, or a lower surface cleaning process of cleaning a lower surface of the substrate W.

A plurality of additional liquid treating chambers 540 is provided and may be provided to be stacked with each other. All of the additional liquid treating chambers 540 may be provided to perform the same process. Optionally, some of the additional liquid treating chambers 540 may be provided to perform different processes.

The interface buffer 560 provides a space in which the substrate W to be transferred between the coating block 20a, the additional liquid treating chamber 540, the exposure device 60, and the developing block 20b temporarily stays during the transferring. A plurality of interface buffers 560 is provided, and the plurality of interface buffers 560 may be provided to be stacked with each other. According to an example, based on an extension line in the longitudinal direction of the transfer chamber 220, the additional liquid treating chamber 540 may be disposed on one side surface thereof, and the interface buffer 560 may be disposed on the other side surface thereof.

The transfer member 580 transfers the substrate W between the coating block 20a, the additional liquid treating chamber 540, the exposure device 60, and the developing block 20b. The transfer member 580 may be provided with one or a plurality of robots. According to an example, the transfer member 580 includes a first robot 5820 and a second robot 5840. The first robot 5820 transfers the substrate W between the coating block 20a or developing block 20b, the additional liquid treating chamber 540, and the interface buffer 560. The second robot 5840 transfers the substrate W from the interface buffer 560 and the exposure device 60.

Each of the first robot 5820 and the second robot 5840 includes a hand on which the substrate W is placed. The hand may be provided to be movable forward and backward, rotatable on an axis parallel to the third direction 6, and movable along the third direction 6. Both the hands of the first robot 5820 and the second robot 5840 may be provided in the same or similar shape as or to the transfer hand 2240 of the transfer robot 224.

Hereinafter, a substrate treating method according to an embodiment of the present invention will be described in detail. The substrate treating method to be described below may be performed by the first heat treating chamber 270. In addition, the controller 8 may control components provided in the first heat treating chamber 270 so as to perform the substrate treating method to be described below by the first heat treating chamber 270.

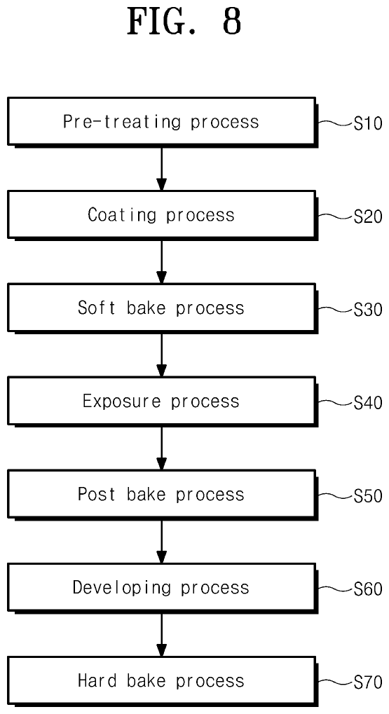

FIG. 8 is a flowchart of a substrate treating method according to an embodiment of the present invention. Referring to FIG. 8, the substrate treating method according to an embodiment of the present invention may include a pre-treating process (S10), a coating process (S20), a soft bake process (S30), an exposure process (S40), a post bake process (S50), a developing process (S60) and a hard bake process (S70). The pre-treating process (S10), the coating process (S20), and the soft bake process (S30) may be performed in the coating block 20a. The exposure process (S40) may be performed in the exposure device 60. The post bake process (S50), the developing process (S60), and the hard bake process (S70) may be performed in the developing block 20b.

The pre-treating process (S10) may perform the liquid treatment of the substrate W. The pre-treating process (S10) may be performed in the liquid treating chamber 290 of the coating block 20a. For example, in the pre-treating process (S10), organic materials, ions, or metal impurities adhering to the surface of the substrate W may be cleaned. In addition, in the pre-treating process (S10), hexamethyldisilazane (HMDS) may be supplied onto the substrate W to hydrophobize the surface of the substrate W. Accordingly, the adhesion between the substrate W and the photoresist may be improved by hydrophobizing the substrate W in the pre-treating process (S10).

After the pre-treating process (S10) has been completed, a pre-bake process of heating the substrate W may be performed. In the pre-bake process, moisture and/or organic materials present on the substrate W may be removed during the pre-treating process (S10). The pre-bake process may be performed in the heat treating chamber 260 of the coating block 20a. In the pre-bake process, after the substrate W is heated, the substrate W may be cooled. After the pre-bake process has been completed, a thin film layer such as an oxide layer such as SiO2, Si3N4, and/or Poly-Si, a first thin film layer TL including a metal, a dielectric layer, and/or a hard mask layer may be formed on the substrate W. Unlike the above-described example, the pre-bake process is not performed after the pre-treating process (S10), and the thin film layer may be directly deposited on the substrate W and the coating process (S20) may also be performed.

The coating process (S20) may be performed in the liquid treating chamber 290 of the coating block 20a. In the coating process (S20), a photoresist is supplied on the substrate W. In the coating process (S20), the photoresist supplied on the substrate W may be an extreme ultraviolet (EUV) photoresist. The EUV photoresist according to an embodiment may be provided as a chemically amplified photoresist or a photoresist having a component including a metal. In the coating process (S20), the photoresist is supplied onto the substrate W, so that the photoresist layer PR may be formed on the surface of the substrate W. That is, the photoresist layer PR may be formed on the surface of the substrate on which the coating process (S20) has been completed, and a plurality of thin film layers DL may be formed under the photoresist layer PR.

The soft bake process (S30) may be performed in the heat treating chamber 260 of the coating block 20a. In the soft bake process (S30), the heat treating may be performed on the substrate W. In the soft bake process (S30), the substrate W with the photoresist layer formed on the surface may be heat-treated. In the soft bake process (S30), an organic solvent present in the photoresist layer PR may be removed by heating the substrate W. In the soft bake process (S30), after the substrate W is heated, the substrate W may be cooled.

The exposure process (S40) may be performed in the exposure device 60. In the exposure process (S40), the properties of the photoresist may be changed by irradiating light to the photoresist layer PR formed on the surface of the substrate W. Before performing the exposure process (S40), a protective liquid may be coated to protect the photoresist layer PR when the exposure is performed on the substrate W. The protective liquid may include a foaming material or a fluorine-based solvent. In addition, the cleaning process of cleaning the upper surface and/or the lower surface of the substrate W may be further performed before and after the exposure process (S40) is performed. In addition, an edge exposure process of exposing the edge region of the substrate W may also be further performed before and after the exposure process (S40) is performed.

The post bake process (S50, post exposure bake; PEB) is a process of performing heat treatment after the exposure is performed on the substrate W. In the post bake process (S50), the substrate W on which the exposure process (S40) has been completed may be heated. In the post bake process (S50), the substrate W may be heated by irradiating laser light to the substrate W. In addition, in the post bake process (S50), the first thin film layer TL including a metal among the plurality of thin film layers DL formed on the substrate W may be targeted and heated.

In the post bake process (S50), exposure energy required in the exposure process (S40) may be lowered by irradiating laser light to the substrate W to supplement the exposure energy required in the exposure process (S40). In addition, in the post bake process (S50), when a chemically amplified EUV photoresist layer PR is coated on the surface of the substrate W, the photoresist layer PR is indirectly heated to activate chemical reactions of the photoresist layer PR. In addition, in the post bake process (S50), when a metal-containing EUV photoresist layer PR is coated on the surface of the substrate W, the photoresist layer PR is directly heated to bake the photoresist layer PR. The post bake process (S50) may be performed in the heat treating chamber 260 of the developing block 20b according to an embodiment of the present invention. For example, the post bake process (S50) may be performed in the first heat treating chamber 270. A detailed description of the post bake process (S50) performed in the first heat treating chamber 270 will be described below.

In the developing process (S60), the photoresist layer PR is removed by supplying a treating liquid to the substrate W. For example, when a positive photoresist layer PR is coated on the substrate W and subjected to the exposure treatment, the photoresist layer PR exposed by supplying the developer to the substrate W is removed, and the unexposed photoresist layer PR may not be removed. Optionally, when a negative photoresist layer PR is coated on the substrate W and subjected to the exposure treatment, the photoresist layer PR exposed by supplying the developer to the substrate W is not removed, and the unexposed photoresist layer PR may be removed. The developing process (S60) may be performed in the liquid treating chamber 290 of the developing block 20b.

In the hard bake process (S70), the substrate W on which the developing process (S60) has been completed is heat-treated. For example, the hard bake process (S70) may perform heating and cooling the substrate W. The hard bake process (S70) may be performed in the second heat treating chamber 280 of the developing block 20b according to an embodiment. In the hard bake process (S70), the substrate W is heated to remove the residual developer and/or organic solvent, and improve the adhesion of the photoresist layer PR. In addition, the hard bake process (S70) may perform cooling the substrate W after heating the substrate W.

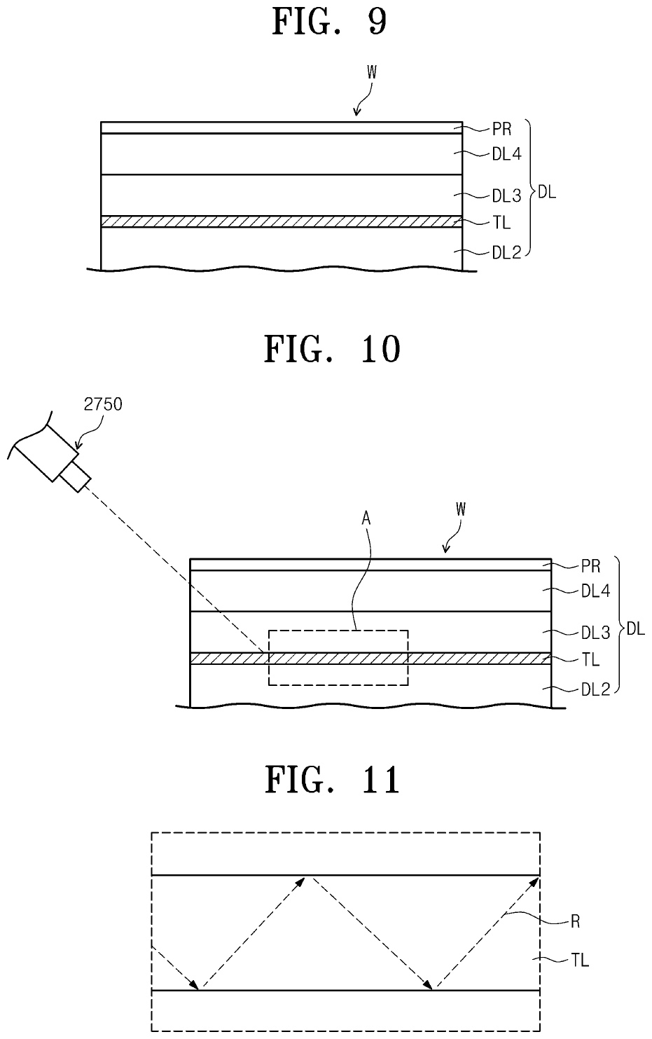

FIG. 9 is a view schematically illustrating the substrate on which the exposure process of FIG. 8 has been completed when viewed from the front. Referring to FIG. 9, the photoresist layer PR is formed on the surface of the substrate W. In addition, the thin film layer DL may be formed below the photoresist layer PR of the substrate W. A plurality of thin film layers DL may be formed. The thin film layer DL may include at least one of an oxide layer such as SiO2, Si3N4, and/or Poly-Si, a first thin film layer TL including a metal, a dielectric layer, or a hard mask layer.

Hereinafter, for convenience of description, it will be described as an example that the thin film layer DL includes a photoresist layer PR, a first thin film layer TL, a second thin film layer DL2, a third thin film layer DL3, and a fourth thin film layer DL4. However, the present invention is not limited thereto, and the number and types of the thin film layers DL formed below the photoresist layer PR may be variously modified.

The first thin film layer TL, the second thin film layer DL2, the third thin film layer DL3, and the fourth thin film layer DL4 are all positioned below the photoresist layer PR. The photoresist layer PR to be described below may be a photoresist layer PR for chemically amplified EUV. The first thin film layer TL may include a metal. According to an example, the first thin film layer TL may function as a power rail for supplying power to transistor cells formed in the thin film layer DL. The second thin film layer DL2 may be disposed below the first thin film layer TL. In addition, the third thin film layer DL3 and the fourth thin film layer DL4 may be sequentially disposed above the first thin film layer TL. Hereinafter, for convenience of description, it will be described as an example that a metal is included only in the first thin film layer TL among the thin film layers DL.

In the post bake process (S50), the laser light L is irradiated only to a layer including a metal among the thin film layers DL stacked in a plurality of layers. For example, in the post bake process (S50), the laser light L may be irradiated by targeting the first thin film layer TL among the plurality of thin film layers DL formed on the substrate W.

FIG. 10 is a view schematically illustrating a state in which laser light is irradiated to the first thin film layer in the post bake process of FIG. 8. FIG. 11 is an enlarged view of part A showing a state in which a heat source is transmitted from the first thin film layer of FIG. 10. Referring to FIGS. 10 and 11, the substrate W may be heated in the inner space of the first heat treating chamber 270. The heating unit 2750 may irradiate laser light L to the first thin film layer TL among the thin film layers DL formed on the substrate W. The laser light L irradiated from the heating unit 2750 is not absorbed in the third thin film layer DL3, the fourth thin film layer DL4, and the photoresist layer PR that are formed above the first thin film layer TL and do not contain a metal. Accordingly, the laser light L irradiated from the heating unit 2750 may be irradiated to the first thin film layer TL including the metal by sequentially passing through the photoresist layer PR, the fourth thin film layer DL4, and the third thin film layer DL3.

The laser light L irradiated from the heating unit 2750 may be obliquely incident on the upper surface of the first thin film layer TL. The inclination of the laser light L irradiated from the heating unit 2750 may be variously changed as needed by changing an angle of the tilting member 2756. As illustrated in FIG. 11, the laser light L obliquely incident on the first thin film layer TL may be reflected inside the first thin film layer TL. Since the first thin film layer TL includes a metal, thermal energy of the laser light L is absorbed in the first thin film layer TL. Accordingly, the laser light L is reflected and flows inside the first thin film layer TL to uniformly transfer thermal energy to the first thin film layer TL.

In addition, according to an embodiment, the layers (e.g., the second thin film layer DL2 and the third thin film layer DL3) stacked above and below the first thin film layer TL among the thin film layers DL stacked on the substrate W do not include metals. Accordingly, even if the laser light L incident on the first thin film layer TL is refracted inside the first thin film layer TL and is incident on the second thin film layer DL2 and the third thin film layer DL3, the laser light L is not absorbed in the second thin film layer DL2 and the third thin film layer DL3 and does not affect the second thin film layer DL2 and the third thin film layer DL3. Accordingly, when the substrate W is heated in the post bake process (S50) according to an embodiment of the present invention, only a specific layer (e.g., the first thin film layer TL) including a metal may be selectively heated.

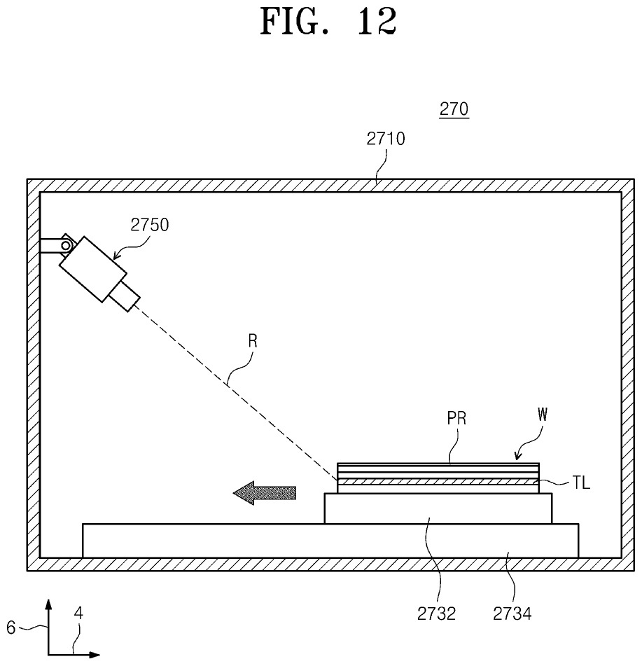

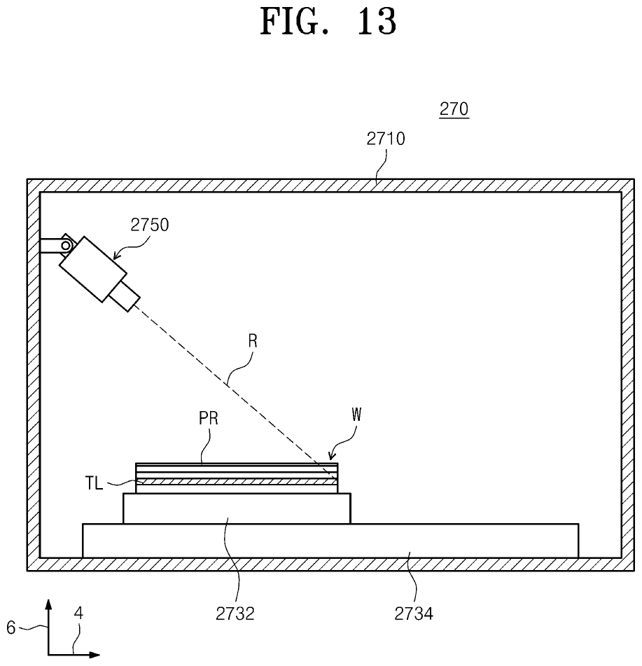

FIG. 12 is a view illustrating a start point of the post bake process of FIG. 8. FIG. 13 is a view illustrating an end point of the post bake process of FIG. 8. Referring to FIGS. 12 and 13, in the post bake process (S50) according to an embodiment of the present invention, the laser light may be obliquely irradiated by targeting the first thin film layer TL including the metal among the thin film layers DL formed on the substrate W. In addition, when the heating unit 2750 irradiates the laser light L in the post bake process (S50), the support unit 2730 may move. The controller 8 may control the moving stage part 2734 while performing the post bake process (S50). As an example, the controller 8 may control the moving stage part 2734 so as to change an area to which the laser light L is irradiated to the first thin film layer TL while the heating unit 2750 irradiates the laser light L to the first thin film layer TL.

As illustrated in FIG. 12, the controller 8 controls the moving stage part 2734 to irradiate the laser light L to one end of the first thin film layer TL, at a start point where the heating unit 2750 irradiates the laser light L to the first thin film layer TL to perform the post bake process (S50). That is, the controller 8 may control the moving stage part 2734 so that the laser light L is irradiated to one end of the substrate W supported on the upper surface of the support part 2732 coupled to the moving stage part 2734.

As illustrated in FIG. 13, the controller 8 controls the moving stage part 2734 to irradiate the laser light L to the other end facing one end of the first thin film layer TL, at an end point where the heating unit 2750 irradiates the laser light L to the first thin film layer TL. That is, when the laser light L incident on the first thin film layer TL is viewed from the top while the post bake process (S50) is performed, the controller 8 may control the moving stage part 2734 so as to move from one end to the other end of the first thin film layer TL. Accordingly, when the post bake process (S50) according to an embodiment of the present invention is performed, the laser light L may be incident while scanning the first thin film layer TL including the metal.

According to the post bake process (S50) according to an embodiment of the present invention described above, the laser light L irradiated from the heating unit 2750 is obliquely incident on the first thin film layer TL, and the laser light L is selectively irradiated only to the first thin film layer TL including the metal to heat the first thin film layer TL, thereby minimizing damage due to the laser light L to different thin film layers DL stacked above and below the first thin film layer TL.

In addition, as the laser light L irradiated from the heating unit 2750 is obliquely incident on the first thin film layer TL, the laser light L may be reflected and flow inside the first thin film layer TL. Uniform heat transfer is enabled inside the first thin film layer TL. Accordingly, the uniformity of various chips formed in the thin film layer DL may be controlled by locally controlling the pattern density inside the first thin film layer TL. That is, the first thin film layer TL may serve as a so-called heat transfer layer. Accordingly, the heat transfer to the photoresist layer PL formed on the surface of the substrate W may be smoothly performed by the first thin film layer TL having the uniform heat transfer. That is, chemical reactions with respect to the chemically amplified EUV photoresist layer PL may be activated. In addition, the exposure energy required in the exposure process (S40) may be reduced.

In addition, in the post bake process (S50) according to an embodiment of the present invention, a separate heat source (e.g., a heater) is not used, and the laser light L is incident on the layer including the metal, thereby uniformly transferring the thermal energy to the thin film layer DL formed on the substrate W.

In addition, while the post baking process (S50) according to an embodiment of the present invention is performed, the movement of the moving stage part 2734 is controlled by the controller 8, so that the laser light L may be uniformly incident on the entire area of the first thin film layer TL including the metal formed on the substrate W. Accordingly, the thermal energy of the laser light L may be efficiently transferred to the inside of the first thin film layer TL.

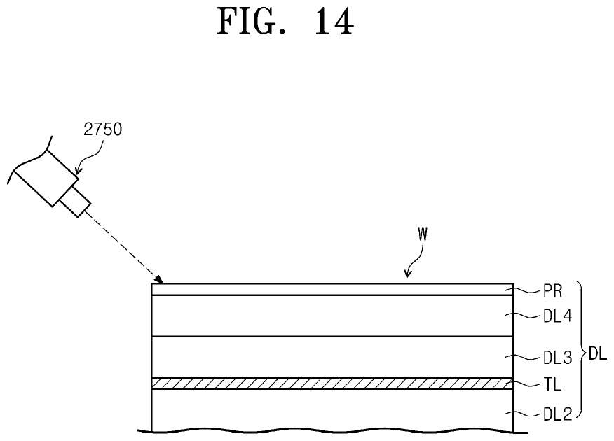

FIG. 14 is a view schematically illustrating a state in which laser light is irradiated to a photoresist layer in the post bake process of FIG. 8. Referring to FIG. 14, in the post bake process (S50) according to an embodiment of the present invention, the photoresist layer PR including the metal among the thin film layers DL formed on the substrate W may be heated. As illustrated in FIG. 14, the heating unit 2750 may irradiate the laser light L to the EUV photoresist layer PR including the metal. Accordingly, the photoresist layer PR including the metal may be heated and baked.

Also, unlike those described above, the laser light L irradiated from the heating unit 2750 may be irradiated by targeting the first thin film layer TL. In the process of irradiating the laser light L to the first thin film layer TL, the laser light L may also be incident on the EUV photoresist layer PR including the metal formed on the surface of the substrate W. Accordingly, while the EUV photoresist layer PR is baked, the first thin film layer TL including the metal may be directly heated to indirectly transfer the heat to the EUV photoresist layer PR.

In the embodiments of the present invention described above, it has been described as an example that in the post bake process (S50) of the present invention, the laser light L is obliquely incident on the thin film layer DL to be heated, but the present invention is not limited thereto. According to an example, the hard bake process (S70) may be performed in the first heat treating chamber 270 of the present invention. In addition, the first heat treating chamber 270 of the present invention may be provided even in the heat treating chamber 260 of the coating block 20a, and the soft bake process (S30) may also be performed in the first heat treating chamber 270.

The foregoing detailed description illustrates the present invention. Further, the above content shows and describes the embodiment of the present invention, and the present invention can be used in various other combinations, modifications, and environments. That is, the foregoing content may be modified or corrected within the scope of the concept of the invention disclosed in the present specification, the scope equivalent to that of the disclosure, and/or the scope of the skill or knowledge in the art. The foregoing embodiment describes the best state for implementing the technical spirit of the present invention, and various changes required in specific application fields and uses of the present invention are possible. Accordingly, the detailed description of the invention above is not intended to limit the invention to the disclosed embodiment. Further, the accompanying claims should be construed to include other embodiments as well.

1. A method for treating a substrate comprising:
heating a substrate provided with a plurality of thin film layers including a photoresist layer formed on a surface; and
irradiating light to a first thin film layer among the plurality of thin film layers to heat the first thin film layer,
wherein the first thin film layer includes metal.

2. The method for treating the substrate of claim 1,
wherein the light is laser light.

3. The method for treating the substrate of claim 2,
wherein the laser light is incident obliquely on an upper surface of the first thin film layer.

4. The method for treating the substrate of claim 1,
wherein the first thin film layer is a layer formed under the photoresist layer.

5. The method for treating the substrate of claim 1,
wherein the first thin film layer is the photoresist layer.

6. The method for treating the substrate of claim 3,
wherein the irradiating of the light to the first thin film layer includes changing an irradiation area at the upper surface of the first thin film while the laser light is irradiated to the first thin film layer, and
wherein the laser light is incident on the irradiation area at the upper surface of the first thin film.

7. The method for treating the substrate of claim 6,
wherein the changing of the irradiation area of the laser light is performed by moving the substrate while the laser light is irradiated.

8. The method for treating the substrate of claim 7,
wherein while the area to which the laser light is irradiated is changed, an incident angle of the laser light is maintained in the same manner.

9. The method for treating the substrate of claim 1,
wherein the heat treating is performed after exposure treatment on the substrate.

10. A heating method for a substrate in a photolithography process including a coating process of coating a photoresist on the substrate, an exposure process of irradiating light to the substrate, and a developing process of supplying a developer to the substrate, the heating method comprising:
heating the substrate formed with a plurality of thin film layers including a photoresist layer formed on a surface; and
irradiating laser light to a first thin film layer including a metal among the plurality of thin film layers to heat the first thin film layer.

11. The heating method of claim 10,
wherein the laser light is incident obliquely on an upper surface of the first thin film layer.

12. The heating method of claim 10,
wherein the first thin film layer is a layer formed under the photoresist layer.

13. The heating method of claim 10,
wherein the first thin film layer is the photoresist layer.

14. The heating method of claim 10,
wherein an area where the laser light is irradiated to the first thin film layer is changed while the laser light is irradiated to the first thin film layer, and
the change of the irradiation area of the laser light is performed by moving the substrate while the laser light is irradiated.

15. The heating method of claim 10,
wherein the heat treating is performed after the exposure process.

16.-20. (canceled)
